(19) United States
(12) Patent Application Publication
(10) Pub. No.: US 2020/0168802 A1
(43) Pub. Date: May 28, 2020

(54) METHOD FOR PREPARING CONJUGATED POLYMER FILM, LIGHT-EMITTING DIODE, DISPLAY DEVICE AND SOLAR CELL

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Zengqiang XIA, Beijing (CN); Qingyun BAI, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 16/611,307

(22) PCT Filed: Nov. 14, 2018
(86) PCT No.: PCT/CN2018/115362

§ 371 Date: Nov. 6, 2019

(30) Foreign Application Priority Data
Mar. 29, 2018 (CN) 201810270635.1

(51) Int. Cl. H01L 51/00; C08J 5/18; D01F 8/14; D01F 8/16; D01F 11/08

(52) U.S. Cl. CPC H01L 51/0036; C08J 5/18; D01F 8/14; H01L 51/5092; D01F 11/08; H01L 51/0043; C08J 2365/00; D01F 8/16

(57) ABSTRACT

The present disclosure relates to a method for preparing a conjugated polymer film, as well as a light-emitting diode, a display device, and a solar energy battery including the conjugated polymer film. A method for preparing a conjugated polymer film according to the present disclosure includes: preparing a fibrous conjugated polymer; and preparing a conjugated polymer film from the fibrous conjugated polymer. Since the fibrous conjugated polymer has a certain length and orientation, it has improved electron mobility in the dimensional direction thereof, and is capable of improving the carrier mobility of the conjugated polymer film.

### CROSS-REFERENCE TO RELATED APPLICATION

This application claims a priority to Chinese Patent Application No. 201810270635.1 filed on Mar. 29, 2018, the disclosures of which are incorporated in their entirety by reference herein.

### TECHNICAL FIELD

The present disclosure relates to the field of display, in particular, to a method for preparing a conjugated polymer film, as well as an organic light-emitting diode, a display device, and a solar cell including the conjugated polymer film.

### BACKGROUND

Organic light-emitting diode (OLED) has the characteristics of high light-emitting brightness, wide window for selecting material, low driving voltage, full cured active illumination, etc., as well as advantages of high definition, wide viewing angle, fast response speed, etc., thereby meeting the development trend of mobile communication and information display in the information age and the requirements of environmentally friendly lighting technology. Thus, it is currently the focus of many researchers.

The organic light-emitting diode and the display device including the organic light-emitting diode generally include a layer in a form of a film, such as an anode, a hole transport layer, a hole injection layer, a light-emitting layer, an electron injection layer, an electron transport layer, and a cathode. The solar cell also includes a layer in a form of film, such as a hole transport layer, a hole injection layer, an electron injection layer, and an electron transport layer. Each of the above layers is usually formed by a vapor deposition technique or a solution film-forming method. The solution film-forming method includes a solution spin coating technique or an inkjet printing technique, and has the advantages of simple operation and the like. However, due to the presence of the solvent, the film material formed by the solution film-forming method is of a loose accumulation state. Therefore, the carrier has a slow transfer rate and a short migration length, thereby reducing the carrier mobility of the component.

### SUMMARY

According to an aspect of the present disclosure, there is provided a method for preparing a conjugated polymer film, including: preparing a fibrous conjugated polymer; and preparing a conjugated polymer film from the fibrous conjugated polymer.

Optionally, the preparing the conjugated polymer film from the fibrous conjugated polymer includes: preparing a dispersion containing a fibrous conjugated polymer; and preparing a conjugated polymer film from the dispersion.

Optionally, the preparing the fibrous conjugated polymer includes:

a sub-step of preparing a composite fiber material: preparing a composite fiber material having a conjugated polymer as an inner layer and a high molecular polymer as an outer layer by a coaxial electrospinning process; and a sub-step of preparing a fibrous conjugated polymer: peeling off the high molecular polymer of the outer layer of the composite fiber material to obtain the fibrous conjugated polymer.

Optionally, the sub-step of preparing the composite fiber material includes: forming an inner layer spinning solution by using a conjugated polymer as a solute, forming an outer layer solution by using a high molecular polymer as a solute; and forming a fiber material having a conjugated polymer as an inner layer and a high molecular polymer as an outer layer by coaxial electrospinning process.

Optionally, the conjugated polymer is at least one selected from poly(3-hexylthiophene), conjugated polymer of naphthalimide and thiophene, polystyrene, polyquinoxaline and polyfluorene.

Optionally, the mass percentage concentration of the conjugated polymer in the inner spinning solution is about 1% to 15%.

Optionally, the high molecular polymer comprises polyethylene terephthalate and/or polymethyl methacrylate.

Optionally, the outer layer solution has a mass percentage concentration of about 1% to 20%.

Optionally, the operating voltage for preforming coaxial electrospinning is 1 kV to 500 kV.

Optionally, the performing the coaxial electrospinning includes: simultaneously spraying the inner layer spinning solution and the outer layer solution onto a plate electrode by using a needle, with a distance between the needle and the plate electrode being greater than 5 cm.

Optionally, the inner spinning solution and the outer layer solution are pumped at a rate of about 0.01 μl/h to 10 ml/h.

Optionally, the sub-step of preparing the fibrous conjugated polymer includes: immersing the fibrous material into a treatment liquid, and subjecting to heating, shaking, and sonication to peel off the high molecular polymer of the outer layer, thereby producing the fibrous conjugated polymer.

Optionally, the treatment liquid comprises at least one of methanol and acetonitrile.

Optionally, the fibrous conjugated polymer is a nanofiber material, and the nanofiber material has a diameter of 1 nm to 200 nm and an aspect ratio of 1000 or more.

According to another aspect of the present disclosure, there is provided an organic light-emitting diode, including a conjugated polymer film of a fibrous conjugated polymer.

Optionally, the fibrous material is a nano fibrous material, and the nano fibrous material has a diameter of 1 nm to 200 nm and an aspect ratio of 1000 or more.

Optionally, the conjugated polymer film is at least one of an electron injection layer, an electron transport layer, and a light-emitting layer in the organic light-emitting diode.

Optionally, the conjugated polymer film comprises a p-type conjugated polymer and/or an n-type conjugated polymer.

According to still another aspect of the present disclosure, there is provided a display device, including the organic light-emitting diode of any one of the above described.

According to still another aspect of the present disclosure, there is provided a solar cell, including a conjugated polymer film of a fibrous conjugated polymer.

Optionally, the fibrous material is a nano fibrous material, and the nano fibrous material has a diameter of 1 nm to 200 nm and an aspect ratio of 1000 or more.

Optionally, the conjugated polymer film layer is at least one of an electron injection layer, an electron transport layer, and a photoelectric conversion layer in a solar cell.

### BRIEF DESCRIPTION OF THE DRAWINGS

FIG. 1 shows a flow chart of a method for preparing a conjugated polymer film according to an embodiment of the present disclosure.

FIG. 2 is a schematic view showing a structure of a coaxial electrospinning device.

FIG. 3 shows a flow chart of a method for preparing a conjugated polymer film layer according to another embodiment of the present disclosure.

FIG. 4 shows a scanning electron micrograph of a nano fibrous conjugated polymer prepared according to Example 1 of the present disclosure.

FIG. 5 shows a scanning electron micrograph of a nano fibrous conjugated polymer prepared according to Example 2 of the present disclosure.

### DETAILED DESCRIPTION

In order to better understand the present disclosure, the specific embodiments of the present disclosure will be described below in conjunction with specific embodiments and examples, but it should be understood that these descriptions are merely used to further illustrate the features and advantages of the present disclosure and are not intended to limit the scope of the present disclosure.

The term “about” as used in the present disclosure refers to a certain deviation from the endpoint value, for example, a certain deviation of ±2%.

In the related art, a layer for electron mobility, for example, an electron injection layer, an electron transport layer, and a light-emitting layer, is often a conjugated polymer organic semiconductor material. However, organic semiconductor materials have their inherent disadvantages, that is, a low electron mobility; and, in solution film-forming methods, such as inkjet printing and spin coating technique, the film-forming materials are usually accumulated in a relatively loose state, directly results in a short transmission length of carriers, especially electrons, on the same molecular chain and readily results in a transition between molecules, thereby resulting in a low carrier mobility. This further seriously affects the material transport of the carrier and the performance of the device. Therefore, the present disclosure proposes a pre-treatment of a conjugated polymer for film-forming material, to be formed into a fibrous conjugated polymer. Since the fibrous conjugated polymer has a certain length and orientation, it has high electron mobility in the dimensional direction thereof, thereby being capable of improving the carrier mobility very well. This further improves the performance of the organic light-emitting diode, the display device, and the solar cell device including a layer of this film.

Further, as a commonly used organic semiconductor material, the conjugated polymer material is usually a rigid material, and it is difficult to form a fibrous material having a uniform and suitable length. The present disclosure produces a polymer semiconductor fiber having good uniformity and controllable size, by using a coaxial electrospinning process and by controlling the concentration of the spinning dispersion, the voltage, and the pumping speed of the coaxial solution. It should be noted that the method has general versatility and is capable of handling a series of conjugated semiconductor materials very well.

Therefore, the technical problem to be solved by the present disclosure is to provide a method for preparing a conjugated polymer film having a high carrier mobility. The film can be used for an organic light-emitting diode, a display device, and a solar cell.

The method for preparing a conjugated polymer film according to the present disclosure has the advantage: since the fibrous conjugated polymer has a certain length and orientation, it has very high electron mobility in the dimensional direction thereof, and is capable of improving the carrier mobility. When the conjugated polymer film prepared by the method is used for an organic light-emitting diode, a display device, and a solar cell, the conjugated polymer film has high carrier mobility, thereby improving the performance of the device.

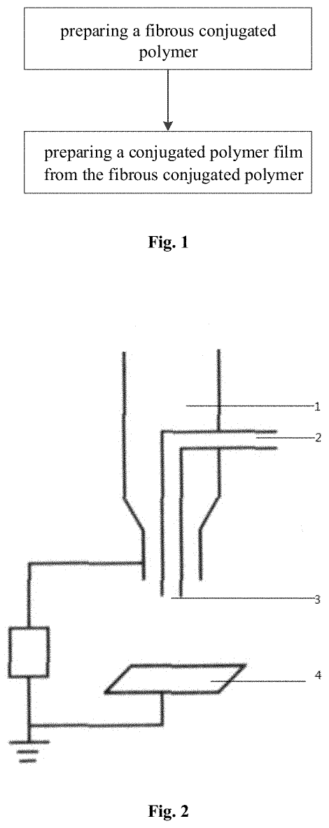

According to one embodiment of the present disclosure, there is provided a method for preparing a conjugated polymer film according to the present disclosure (see FIG. 1), including the following specific steps of: preparing a fibrous conjugated polymer; and preparing a conjugated polymer film from the fibrous conjugated polymer. Optionally, the preparing the conjugated polymer film from the fibrous conjugated polymer includes: preparing a dispersion containing a fibrous conjugated polymer; and preparing a conjugated polymer film from the dispersion. For example, the dispersion is prepared into a conjugated polymer film by a solution method.

The conjugated polymer film according to the present disclosure can be used in a semiconductor device, such as an organic light-emitting diode, a display device, or a solar cell. Since the fibrous conjugated polymer material in the film layer has a certain length and orientation, it has a high electron mobility in the dimensional direction thereof. Thereby, the carrier mobility can be improved, thereby improving the device performance.

In an optional embodiment, the solution film-forming method may include any one of, for example, an inkjet printing method, a screen printing method, and a spin coating method. Optionally, the solution film-forming method is specifically: coating a dispersion containing a fibrous conjugated polymer on a support or other film layer by spin coating, screen printing or inkjet printing, and obtaining a conjugated polymer film by drying.

Since the fibrous conjugated polymer is used for preparing a film having a relatively small thickness, the fibrous conjugated polymer may be a nano-scaled fibrous conjugated polymer. Optionally, the fibrous conjugated polymer has a diameter of 1 nm to 200 nm, and further optionally 10 nm to 150 nm. Optionally, the fibrous conjugated polymer has an aspect ratio of 1000 or more, and further optionally 2000 or more. When the diameter and length (or aspect ratio) of the fibrous conjugated polymer fall within the above preferred range, very excellent mobility properties can be obtained. Further optionally, the length and diameter of the fibrous conjugated polymer material are uniform, and the mobility of the prepared conjugated polymer film layer is more excellent.

The segment of the conjugated polymer belongs to a semiconductor material, and may be a p-type conjugated polymer or an n-type conjugated polymer. The solution may contain a p-type fibrous conjugated polymer or an n-type fibrous conjugated polymer, and may further contain both a p-type fibrous conjugated polymer and an n-type fibrous conjugated polymer. The solution containing both a p-type fibrous conjugated polymer and an n-type fibrous conjugated polymer can construct a nano-scale interpenetrating network structure, and the conjugated polymer film layer obtained by a p-type fibrous conjugated polymer and an n-type fibrous conjugated polymer through a solution method and a film-forming method has remarkably improved separation and transmission rate of electrons and holes.

Optionally, the conjugated polymer may be an electron injection layer, an electron transport layer or a light-emitting layer. Optionally, the conjugated polymer includes at least one selected from poly(3-hexylthiophene) (P3HT), conjugated polymer of naphthalimide and thiophene (NDI), polystyrene, polyquinoxaline and polyfluorene. The conjugated polymer of the naphthalimide and thiophene may be poly{2,7-[(9,9-bis(N,N-dimethylpropyl-3-amino)fluorene]-alt-5,5′-[2,6-(bis-2-thienyl)-N,N′-diisooctyl-1,4,5,8-naphthalenetetracarboxydiimide]} (PNDIT-F3N) or poly{2,7-[9,9′-bis(N,N-dimethylpropyl-3-ethylammonium bromide)fluorene]-alt-5,5′-[2,6-(bis-2-thienyl)-N,N′-diisooctyl-1,4,5,8-naphthalenetetracarboxydiimide]} (PNDIT-F3N-Br).

In the related art, the segment of the conjugated polymer has rigidity and is difficult to be prepared into a fibrous material. The method of the present disclosure overcomes the difficulties of the related art, and obtains a fibrous conjugated polymer. Optionally, the method for preparing a fibrous conjugated polymer according to the present disclosure includes preparing a fibrous conjugated polymer, in which the step of preparing the fibrous conjugated polymer includes: a sub-step of preparing a composite fiber material: preparing a composite fiber material having a conjugated polymer as an inner layer and a high molecular polymer as an outer layer by a coaxial electrospinning process; and a sub-step of preparing a fibrous conjugated polymer: peeling off the high molecular polymer of the outer layer of the composite fiber material to obtain the fibrous conjugated polymer.

In an optional embodiment of the present disclosure, the step of preparing the fibrous conjugated polymer specifically includes the sub-step of preparing a composite fiber material and the sub-step of preparing a fibrous conjugated polymer as follows. Optionally, the sub-step of preparing the composite fiber material specifically includes: forming an inner layer spinning solution by using a conjugated polymer as a solute, forming an outer layer solution by using a high molecular polymer as a solute; and forming a composite fiber material having a conjugated polymer as an inner layer and a high molecular polymer as an outer layer by a coaxial electrospinning process. Since the high molecular polymer is easily formed to be fibrous by a spinning method, the outer layer is formed to be fibrous. After the outer layer is formed to be fibrous, the conjugated polymer is wrapped therein, so that the conjugated polymer is also formed to be fibrous in the inner layer.

The conjugated polymer is dissolved in a solvent, to form an inner layer spinning solution having a conjugated polymer as a solute. The solvent is a good solvent for the conjugated polymer, and may be selected from a solvent having good solubility and low boiling point, such as chloroform, dichloromethane or chlorobenzene. From the viewpoint of obtaining dimensional uniformity as well as suitable diameter and length of the nanofibers, the inner layer spinning solution has a mass percent concentration of about 1% to 15%. Further, in order to obtain more uniform nanofibers, the mass percentage concentration may be selected from 2% to 10%, and even optionally from 3% to 8%.

From the viewpoint of obtaining dimensional uniformity as well as suitable diameter and length of nanofibers, the high molecular polymer as the outer layer may be selected from a polymer having a soft segment, that is, a polymer chain having a high degree of freedom of chemical bond. The main chain of the polymer having a flexible segment is mainly composed of a C—C single bond, a C—O single bond, and an O—O bond, and the molecular weight may be 10,000 or more. Since the high molecular polymer has a long molecular chain and chain flexibility, it is possible to spin well and to easily control the size of the spinning. Further, the high molecular weight polymer is a polymer having a soft segment with a relative molecular weight of 10,000 to 300,000. Specifically, the high molecular polymer includes polyethylene terephthalate (PET) and/or polymethyl methacrylate (PMMA). In an optional embodiment, the high molecular polymer may be selected from PET having a relative molecular weight of 100,000 to 200,000 or PMMA having a relative molecular weight of 40,000 to 60,000 (or even 50,000). When a specific polymer having the above relative molecular weight is selected, more excellent spinning properties can be obtained.

Optionally, the mass percentage of the high molecular polymer in the outer layer solution is about 1% to 20%. Further, in order to obtain better spinning performance and to obtain more uniform nanofibers, the mass percentage concentration may be selected from 2% to 10%, and even optionally from 2% to 6%.

A schematic of a coaxial electrospinning apparatus used in embodiments of the present disclosure is shown in FIG. 2. In FIG. 2, 1 is an input channel of the outer layer solution, 2 is an input channel of the inner layer spinning solution, 3 is a needle, and 4 is a plate electrode. The outer layer solution and the inner layer spinning solution are ejected through the needle 3 and are drawn by an electric field, to form a fibrous material.

According to the type of conjugated polymer and high molecular polymer, the concentration of the outer layer solution, the inner spinning solution, etc., the operating voltage of the coaxial electrospinning process can be appropriately selected, to obtain a fibrous material having a uniform size.

According to requirement to the diameter of the fiber material, the distance between the needle and the plate electrode can be appropriately adjusted. The farther the distance between the needle and the plate electrode, the smaller the diameter of the fibrous material.

The pumping speeds of the inner spinning solution and the outer layer solution also affect the diameter of the prepared fibrous material. The higher the pumping rate of the outer layer solution, the smaller the diameter of the fibrous material; and vice versa.

In an optional embodiment of the present disclosure, by adjusting the spinning voltage in the coaxial electrospinning process, the distance between the needle and the plate electrode, and the pumping speed of the solution according to the concentrations of the inner spinning solution and the outer layer solution, nanofiber materials having the best length and diameter and uniform size can be formed. For example, the operating voltage during the coaxial electrospinning process may be about 1 kV to 500 kV, or even 10 kV to 300 kV, and further optionally 20 kV to 150 kV. Optionally, when the concentrations of the inner layer spinning solution and the outer layer solution fall within the above-selectable range, the distance between the needle and the plate electrode may be set to be greater than 5 cm, for example, greater than 10 cm, or even greater than 20 cm; and the pumping speeds of the inner layer spinning solution and the outer layer solution are about 0.01 μl/h to 10 ml/h, even 0.05 μl/h to 5 ml/h, for example 0.1 μl/h, 1 μl/h, 100 μl/h, 1 ml/h and 5 ml/h. By suitably setting the above process parameters, a nano fibrous material having uniform size as well as optimum length and aspect ratio can be obtained.

In addition, in the electrospinning process, a volatile solvent may be selected as a solvent in the inner spinning solution. Further, it is also possible to improve the spinning effect by heating the inner layer spinning solution, thereby achieving the effect of improved spinning.

The method of preparing the fibrous conjugated polymer specifically includes the sub-step of preparing a composite fiber material and the sub-step of preparing a fibrous conjugated polymer. Optionally, a sub-step of preparing a fibrous conjugated polymer is: peeling off the high molecular polymer of the outer layer of the composite fiber material to obtain the fibrous conjugated polymer. Optionally, the sub-step of preparing the fibrous conjugated polymer specifically includes: immersing the fibrous material into a treatment liquid, and subjecting to heating, shaking, and sonication to peel off the high molecular polymer of the outer layer, thereby producing the fibrous conjugated polymer.

The effect of the treatment liquid is to remove the polymer of the outer layer. Therefore, the treatment liquid has a good solubility for a high molecular polymer, but it is difficult to dissolve the conjugated polymer of the inner layer. The treatment liquid is directly related to the selection of the conjugated polymer and the high molecular polymer. For example, when the conjugated polymer is poly(3-hexylthiophene) and the high molecular polymer is polyethylene terephthalate, the treatment liquid may be selected from methanol. When the conjugated polymer is poly(3-hexylthiophene) and the high molecular polymer is polymethyl methacrylate, the treatment liquid may be selected from acetonitrile. The treatment liquid used in the method of the present disclosure is not limited to these specific types, and any solvent can be used, as long as it can achieve the above object.

In order to completely peel off the high molecular polymer of the outer layer, heating, shaking and sonication can be selected. The heating, shaking, and sonication can be performed together. Optionally, such processing can be performed three or more times. Finally, a fibrous conjugated polymer can be obtained.

FIG. 3 shows a flow chart of a method for preparing a conjugated polymer film according to an optional embodiment of the present disclosure. The method for preparing a conjugated polymer film includes the following specific steps: preparing a composite fiber material having a conjugated polymer as an inner layer and a high molecular polymer as an outer layer by a coaxial electrospinning process; peeling off the high molecular polymer of the outer layer of the composite fiber material to obtain the fibrous conjugated polymer; preparing a dispersion containing a fibrous conjugated polymer; and preparing a conjugated polymer film layer from the dispersion.

The conjugated polymer film layer prepared according to the present disclosure can be used in an organic light-emitting diode, a display device, or a solar cell.

According to an aspect of the present disclosure, there is provided an organic light-emitting diode including the conjugated polymer film prepared by the method of any of the above embodiments, in which the conjugated polymer film is mainly composed of a fibrous material. Optionally, the fibrous material is a nano fibrous material, and the nano fibrous material has a diameter of 1 nm to 200 nm and an aspect ratio of 1000 or more.

As compared with the electron mobility of the conjugated polymer film layer prepared by the conventional solution film-forming method, the electron mobility of the conjugated polymer film prepared according to the method of the present disclosure is significantly improved. Therefore, the conjugated polymer film layer prepared according to the method of the present disclosure is mainly used as a layer for electron mobility, including an electron injection layer, an electron transport layer, or a light-emitting layer.

Optionally, the conjugated polymer film layer comprises a p-type conjugated polymer and an n-type conjugated polymer. The p-type conjugated polymer and the n-type conjugated polymer can be constructed into a nano-scale interpenetrating network structure, thereby improving the separation and transport of electrons and holes.

According to another embodiment of the present disclosure, a display device including the organic light-emitting diode of the above embodiment is also disclosed.

According to another embodiment of the present disclosure, there is also disclosed a solar cell, including the conjugated polymer film prepared by the method of any of the above embodiments, in which the conjugated polymer film layer is mainly composed of fibrous material. Optionally, the fibrous material is a nano fibrous material, and the nano fibrous material has a diameter of 1 nm to 200 nm and an aspect ratio of 1000 or more.

In order to further understand the technical solutions of the present disclosure, the method for preparing the conjugated polymer film layer provided by the present disclosure and the use thereof will be described in detail below in conjunction with specific embodiments. The protection scope of the present disclosure is not limited by the following Examples.

### EXAMPLE

### Example 1

A chloroform solution of poly(3-hexylthiophene) having a mass percentage concentration of 8% was used as an inner layer spinning solution, and an ethanol solution of polyethylene terephthalate having a mass percentage concentration of 3% was used as an outer layer solution. The working voltage was 30 KV, the distance between the needle and the plate electrode was 20 cm, and the inner spinning solution and the outer layer solution were pumped at a pumping rate of 0.1 μl/h, to obtain a nanofiber material. The diameter of the nanofiber material is uniformly stable at about 100 nm, and the aspect ratio is 2,000 or more.

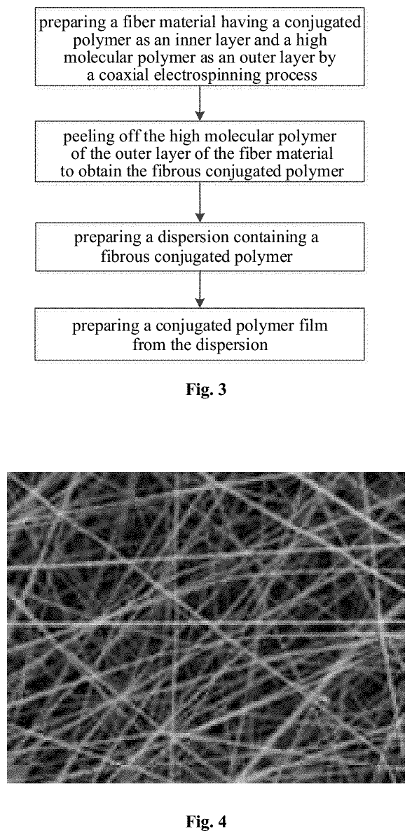

The nanofiber material is immersed in methanol, heated, shaken, and sonicated. The treatment was repeated three times, and the outer layer of polyethylene terephthalate was completely peeled off to obtain nano fibrous poly(3-hexylthiophene). FIG. 4 is a scanning electron micrograph of a nano fibrous conjugated polymer prepared according to this Example.

The nano fibrous poly(3-hexylthiophene) was formed into a solution, and a poly(3-hexylthiophene) film was obtained by an inkjet printing method.

As a comparison, a poly(3-hexylthiophene) film layer prepared by a conventional solution method (e.g., spin coating method) in the related art was used as a comparative example. The comparison results show that by comparing the organic light-emitting diode of the poly(3-hexylthiophene) film prepared in this example and the organic light-emitting diode of the poly(3-hexylthiophene) film prepared in a conventional solution method, the charge mobility for this example is significantly improved.

### Example 2

A chloroform solution of a conjugated polymer of naphthalimide and thiophene having a mass percentage concentration of 5% was used as an inner layer spinning solution, and an ethanol solution of polyethylene terephthalate having a mass percentage concentration of 3% was used as an outer layer solution. The working voltage was 45 KV, the distance between the needle and the plate electrode was 20 cm, and the inner spinning solution and the outer layer solution were pumped at a pumping rate of 0.1 μl/h, to obtain a nanofiber material. The diameter of the nanofiber material is uniformly stable at about 150 nm, and the aspect ratio is 2,000 or more.

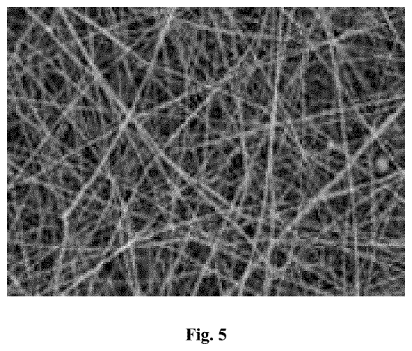

The nanofiber material is immersed in methanol, heated, shaken, and sonicated. The treatment was repeated three times, and the outer layer of polyethylene terephthalate was completely peeled off to obtain a conjugated polymer of nano fibrous naphthalimide and thiophene. FIG. 5 is a scanning electron micrograph of a nano fibrous conjugated polymer prepared according to this Example.

The conjugated polymer of the nano fibrous naphthalimide and thiophene was formed into a solution, which was prepared by an inkjet printing method into a conjugated polymer film layer of naphthalimide and thiophene.

As a comparison, a conjugated polymer film layer of naphthalimide and thiophene prepared by a conventional solution method (e.g., spin coating method) in the related art was used as a comparative example. The comparison results show that by comparing the organic light-emitting diodes of the conjugated polymer film of naphthalimide and thiophene prepared in this example and the organic light-emitting diodes of the conjugated polymer film of naphthalimide and thiophene prepared in a conventional solution method, the charge mobility for this example is significantly improved.

The above Examples is merely used for helping to understand the method according to the present disclosure and its inventive concept. It should be noted that a person skilled in the art may make further improvements and modifications to the disclosure without departing from the principle/spirit of the present disclosure, and these improvements and modifications shall also fall within the scope of the present disclosure. Therefore, the present disclosure will not be limited to the Examples shown herein, but should conform to the widest scope consistent with the principles and novel features disclosed herein.

1. A method for preparing a conjugated polymer film, comprising: preparing a fibrous conjugated polymer; and preparing a conjugated polymer film from the fibrous conjugated polymer.

2. The method of claim 1, wherein the step of preparing the conjugated polymer film from the fibrous conjugated polymer comprises: preparing a dispersion containing a fibrous conjugated polymer; and preparing a conjugated polymer film from the dispersion.

3. The method of claim 1, wherein the step of preparing the fibrous conjugated polymer comprises:
a sub-step of preparing a composite fiber material: preparing a composite fiber material having a conjugated polymer as an inner layer and a high molecular polymer as an outer layer by a coaxial electrospinning process; and
a sub-step of preparing a fibrous conjugated polymer: peeling off the high molecular polymer of the outer layer of the composite fiber material to obtain the fibrous conjugated polymer.

4. The method of claim 3 wherein the sub-step of preparing the composite fiber material comprises:
forming an inner layer spinning solution by using a conjugated polymer as a solute, and forming an outer layer solution by using a high molecular polymer as a solute; and
preparing a fiber material having a conjugated polymer as an inner layer and a high molecular polymer as an outer layer by a coaxial electrospinning process.

5. The method of claim 1, wherein the conjugated polymer is at least one selected from poly(3-hexylthiophene), conjugated polymer of naphthalimide and thiophene, polystyrene, polyquinoxaline or polyfluorene.

6. The method of claim 4, wherein the inner layer spinning solution has a mass percentage concentration of about 1% to 15%.

7. The method of claim 3, wherein the high molecular polymer comprises polyethylene terephthalate and/or polymethyl methacrylate.

8. The method of claim 4, wherein the outer layer solution has a mass percentage concentration of about 1% to 20%.

9. The method of claim 3, wherein an operating voltage for performing the coaxial electrospinning is about 1 kV to 500 kV.

10. The method of claim 4, wherein the performing the coaxial electrospinning comprises: simultaneously spraying the inner layer spinning solution and the outer layer solution onto a plate electrode by using a needle, with a distance between the needle and the plate electrode being greater than 5 cm.

11. The method of claim 4, wherein the inner spinning solution and the outer layer solution are pumped at a rate of about 0.01 μl/h to 10 ml/h.

12. The method of claim 2, wherein the sub-step of preparing the fibrous conjugated polymer comprises:
immersing the fibrous material into a treatment liquid, and subjecting it to heating, shaking, and sonication to peel off the high molecular polymer of the outer layer of the fiber material, thereby producing the fibrous conjugated polymer.

13. The method of claim 12, wherein the treatment liquid comprises at least one of methanol and acetonitrile.

14. The method of claim 1, wherein the fibrous conjugated polymer is a nanofiber material, and the nanofiber material has a diameter of 1 nm to 200 nm and an aspect ratio of 1000 or more.

15. An organic light-emitting diode, comprising a conjugated polymer film of a fibrous conjugated polymer.

16. The organic light-emitting diode of claim 15, wherein the fibrous material is a nano fiber material, and the nanofiber material has a diameter of 1 nm to 200 nm and an aspect ratio of 1000 or more.

17. The organic light-emitting diode of claim 15, wherein the conjugated polymer film is at least one of an electron injection layer, an electron transport layer, or a light-emitting layer in the organic light-emitting diode.

18. The organic light-emitting diode of claim 15, wherein the conjugated polymer film comprises a p-type conjugated polymer and/or an n-type conjugated polymer.

19. A display device, comprising the organic light-emitting diode of claim 17.

20. A solar cell, comprising a conjugated polymer film of a fibrous conjugated polymer, wherein the fibrous material is a nano fibrous material, and the nano fibrous material has a diameter of 1 nm to 200 nm and an aspect ratio of 1000 or more; and wherein the conjugated polymer film is at least one of an electron injection layer, an electron transport layer, or a photoelectric conversion layer.

21.-22. (canceled)
